(19) United States
(12) Patent Application Publication
(10) Pub. No.: US 2016/0133672 A1
(43) Pub. Date: May 12, 2016

(54) Hybrid Perovskite with Adjustable Bandgap

(71) Applicant: Sharp Laboratories of America, Inc., Camas, WA (US)

(72) Inventors: Alexey Koposov, Vancouver, WA (US); Karen Nishimura, Washougal, WA (US); Wei Pan, Vancouver, WA (US)

(21) Appl. No.: 14/997,492

(22) Filed: Jan. 16, 2016

Related U.S. Application Data
(63) Continuation-in-part of application No. 14/320,691, filed on Jul. 1, 2014.

(51) Int. Cl. H01L 27/30; H01L 51/44; H01L 31/032; H01L 31/0224; H01L 31/18; H01L 31/0687

(52) U.S. Cl. CPC H01L 27/302; H01L 31/18; H01L 31/0687; H01L 31/0322; H01L 31/022466; H01L 51/442; H01L 31/0326; H01L 2031/0344

(57) ABSTRACT

A method is provided for preparing a thin film of perovskite material having an adjustable bandgap. The method forms a thin film of material having the formula BX₂, where anionic part X is a halide, and where the cation B is lead (Pb), tin (Sn), or germanium (Ge). A solution is formed of materials with the formulas A¹X and A²X, where cation A¹ is formamidinium, and where cation A² is an organic cation having a larger size larger than a methylammonium cation. The method deposits the solution over the BX₂ thin film, and forms a perovskite material having the formula A¹_{1-Y}A²_{y}BX₃. For example, the A² cation may be an ammonium cation such as ethylammonium, guanidinium, dimethylammonium, acetamidinium, or substituted derivatives of the above-mentioned ammonium cations. In one aspect, the perovskite material A¹BX₃ may be formamidinium iodide (FAI), and A²BX₃ may be ethylammonium iodide (EtAI). Tandem solar cells are also provided.

### RELATED APPLICATIONS

This application is a Continuation-in-part of an application entitled, PLANAR STRUCTURE SOLAR CELL WITH INORGANIC HOLE TRANSPORTING MATERIAL, invented by Alexey Koposov et al, Ser. No. 14/320,691, filed on Jul. 1, 2014, Attorney Docket No. untitled SLA3386, which is incorporated herein by reference.

### BACKGROUND OF THE INVENTION

1. Field of the Invention

This invention generally relates to solar cells and, more particularly, to hybrid perovskite material suitable for use in a tandem solar cell.

2. Description of the Related Art

FIG. 1 is a partial cross-sectional view of an exemplary silicon (Si) solar cell (prior art). Conventional photovoltaic cells are commonly composed of doped silicon with metallic contacts deposited on the top and bottom. The doping is normally applied to a thin layer on the top of the cell, producing a p-n junction which creates an environment for carrier separation. Photons that hit the top of the solar cell are either reflected or transmitted into the cell. Transmitted photons have the potential to give their energy, generating an electron-hole pair, if their energy hv is higher than the bandgap energy Eg. In the depletion region, the drift electric field E_{drift} accelerates both electrons and holes towards their respective n-doped and p-doped regions.

Double-junction or tandem solar cells include multiple solar cells made of different semiconductor (absorber) materials. Each absorber material produces electric current in response to different wavelengths of light and voltage related to the bandgap of the material. The use of multiple semiconducting materials permits a more efficient absorbance of a broader range of wavelengths, improving the cell's sunlight to electrical energy conversion efficiency. Generally, the top cell of the tandem structure absorbs low wavelengths (higher energy light), while the bottom cell absorbs higher wavelengths (lower energy light). The currents produced by cells have to match, while the voltage obtained from a tandem is a result of summation of voltages from each cell. While conventional single-junction cells have a maximum theoretical efficiency of 34%, a tandem could produce up to 42% at one sun illumination. Theoretically, an infinite number of junctions would have a limiting efficiency of 86.8% under highly concentrated sunlight. Commercial examples of tandem, two layer cells are widely available at 30% efficiency under one-sun illumination, and improve to around 40% under concentrated sunlight. However, this efficiency is gained at the cost of increased complexity and manufacturing price. Over the years a number of possible combinations have been proposed for the fabrication of tandem solar structures. However, due to manufacturing costs the primary research interest has been devoted to tandem solar cells that utilized mature technologies such as Si, copper indium gallium selenide (CIGS), or even the more problematic copper zinc tin selenide/sulfide (CZTS) as a bottom subcell. As discussed below, recently emerging perovskite materials have demonstrated a great potential for their use in the tandem solar cell structure.

FIG. 2 is a partial cross-sectional view of an exemplary CIGS solar cell (prior art). Glass 200 is commonly used as a substrate, although flexible substrates such as polyimide or metal foils may also be used. A molybdenum (Mo) metal layer 202 serves as the back contact and reflects most unabsorbed light. A p-type CIGS absorber layer 204 is grown and a thin n-type buffer layer 206, such as cadmium sulfide (CdS) is deposited on the absorber. The n-type buffer 206 is covered by a transparent conductive oxide (TCO) 208, such as aluminum (Al)-doped zinc oxide, to carry electrons to the top electrode 210.

FIGS. 3A and 3B are schematic partial cross-sectional views of conventional perovskite solar cells with planar architecture (prior art). Recently, hybrid organic/inorganic perovskite materials have drawn a tremendous interest in academic and industrial community. This class of materials, already known for many years, has recently demonstrated excellent performance when applied to solar cells. The photovoltaic application benefits mostly from the perovskite materials' high absorption coefficient, high carrier mobility, low exciton binding energy, simplicity, and cost of material preparation. Perovskite solar cells function efficiently in a number of somewhat different architectures depending on the nature of the top and bottom electrode. In FIG. 3A, a sensitized perovskite solar cell, positive charges are extracted by the transparent bottom electrode (cathode). The perovskite functions mainly as a light absorber, and charge transport occurs in other materials. Similar to the sensitization in dye-sensitized solar cells, the perovskite material is infiltrated into a charge-conducting mesoporous (mp) scaffold—most commonly titanium oxide (TiO₂)—as a light-absorber. The photogenerated electrons are transferred from the perovskite layer to the mesoporous sensitized layer through which they are transported to the electrode and extracted into the circuit. The positive charges travel to the hole transport layer (generally organic), where they are conducted to the cathode.

In FIG. 3B, a thin-film perovskite solar cell, the majority of the electron or hole transport occurs in the bulk of the perovskite itself. The thin film solar cell architecture is based on the finding that perovskite materials can also act as a highly efficient, ambipolar charge-conductor. After light absorption and subsequent charge-generation, both negative and positive charge carriers are transported through the perovskite to charge selective contacts. Perovskite solar cells emerged from the field of dye-sensitized solar cells, so the sensitized architecture was initially used, but over time it has become apparent that they function well, if not ultimately better, in a thin-film architecture.

Thin film perovskite architecture is of particular interest not only because of its simplicity of preparation, but also due to its potential to form a two junction tandem structure with other solar cells, such as Si, CIGS, or CZTS.

A two junction tandem structure uses two different light absorbing materials, each of them has distinct energy band gap. Usually, a wider band gap material (top subcell) is overlaid on top of a narrower bandgap material (bottom subcell). The remaining light that is not absorbed by the top subcell is absorbed by the bottom subcell, which has the narrow bandgap. Bandgap generally refers to the energy difference, in electron volts (eV), between the top of the valence band and the bottom of the conduction band. The commonly studied perovskite, methylammonium iodoplumbate, has a bandgap of 1.54 eV, making it a good candidate for the top cell in conjunction with conventional silicon or CIGS as the bottom cell.

However, the optimal structure of the tandem cell requires not only perfect interfaces between two parts of the solar cell, but also requires matched current between the top and bottom solar cells to ensure full advantage of a tandem structure. The current matching is generally achieved by selecting top and bottom subcells with appropriate bandgaps: each of the subcells converts part of the solar spectrum and produces the same currents. Therefore, the top subcell also serves as wavelength cut-off filter. Most of the remaining light, which has lower photon energies than the top cell bandgap, is absorbed by the bottom cell. If a conventional Si cell is used as the bottom subcell (1.1 eV), then due to this narrow bandgap, the top subcell perovskite should have a bandgap around of 1.6-1.7 eV, depending on the final cell external quantum efficiency (EQE) after fabrication.

After the first demonstration of a hybrid perovskite solar cell, many bandgap tuning efforts were investigated. The first and most common example of bandgap tuning was demonstrated through the preparation of the perovskite with mixed anionic composition. For instance, the preparation of mixed bromides(Br)/iodides(I), where the ratio of I/Br was varied, to allow the tuning of the bandgap of the final perovskite. The preparation of mixed halogen ions does not influence the general scheme of preparation of the solar cell, which makes it very attractive. It makes the perovskite not only suitable for tandem with Si application, but also for the potential application in building integrated photovoltaics (PVs) with various colors. However, despite the promise of such a simple technique, it has recently been found that there is a fundamental problem with the use of such mixed halogenides.

In particular, it was discovered that upon illumination the mixed halogen ions undergo phase separation, caused by ionic drift. This ionic drift (or migration) of halide atoms results in the formation of separate methylammonium lead bromide “islands”, having a size of approximately 50 nanometers (nm), inside the methylammonium lead iodide. As the result of phase separation, the perovskite becomes a solid mixture of materials with two different bandgaps, creating trap sites inside the material. Therefore, the mixed halogenides approach usually does not demonstrate good performance in solar devices, as both current and voltage are low. In such devices the voltage is dictated by the bandgap of the methylammonium lead iodide, which has a low bandgap, while in a true alloy (mixed iodide bromide) improvement of voltage should be seen due to the increased bandgap of the alloyed material.

Therefore, the route that has been viewed as a simple pathway to tune the bandgap of perovskite does not generate stable solar cells with the expected efficiencies due to aforementioned “ionic drift”. Other methods are required for bandgap tuning. Fortunately, the perovskite material, having a general structure of ABX₃, offers a degree of flexibility for the exchange of elements in various positions. For example, it allows not only the variation of the anionic part X, but also the cations (A or B). In particular, it has been shown that the substitution of the central cation—B could lead to mixed lead/tin perovskites.

However, the exchange of A-site cation for the bandgap tuning has not been reported. Only a mixture of methylammonium and formamidinium iodides has been reported. Depending on the composition, and the amount of formamidinium iodide introduced, the EQE absorption edge varied from 760 nm to 800 nm, which is still not enough to be useful in a perovskite/Si tandem structure. In addition, it is commonly understood that methylammonium based perovskite lacks chemical and thermal stability and, therefore, is unlikely to be a desirable solar cell material. Thus, using mixed methylammonium and formamidinium iodides for A-site cation appears to be a poor solution.

It would be advantageous if a stable perovskite could be synthesized that is capable of bandgap tuning without major structural changes.

### SUMMARY OF THE INVENTION

Disclosed herein is a new perovskite formation pathway to form planar thin films applicable to tandem solar cells with silicon (Si), copper indium gallium selenide (CIGS), or copper zinc tin selenide/sulfide (CZTS) subcells. The bandgap of this perovskite is tunable through A-site cation exchange using formamidinium iodide and ethylammonium iodide to ensure chemical stability. In particular, a thin film lead iodide may be deposited using thermal evaporation in vacuum to achieve a perfectly planar morphology. Then, the as-deposited planar thin films undergo a conversion process to the desired perovskite material. The conversion is achieved through the exposure of the lead iodide film to the mixture of formamidinium iodide and ethylammonium iodide in isopropanol. This results in a chemically and thermally stable perovskite thin film with an adjustable bandgap achieved through controlling the composition of the mixture.

It should be also be noted that some perovskite materials have been reported to be thermally and (or) chemically unstable, thus it is very important to focus only on the stable materials. One example of such is formamidinium-based perovskite, which demonstrates good thermal stability compared to other known perovskites.

Accordingly, a method is provided for preparing a thin film of perovskite material having an adjustable bandgap. The method forms a thin film of material having the formula BX₂, where anionic part X is a halide, and where the cation B is lead (Pb), tin (Sn), or germanium (Ge). A solution is formed of materials with the formulas A¹X and A²X, where cation A¹ is formamidinium, and where cation A² is an organic cation having a larger size larger than a methylammonium cation. The method deposits the solution over the BX₂ thin film, and forms a perovskite material having the formula A¹_{1-Y}A²_{y}BX₃, with or without subsequent annealing.

For example, the A² cation may be an ammonium cation such as ethylammonium, guanidinium, dimethylammonium, acetamidinium, or substituted derivatives of the above-mentioned ammonium cations. In one aspect, the perovskite material A¹BX₃ may be formamidinium iodide (FAI), and A²BX₃ may be ethylammonium iodide (EtAI). The FAI and EtAI may form a material with the formula FA_{1-y}EtA_{Y}PbI₃. The bandgap of perovskite material is responsive to the proportion of EtAI to FAI, where a bandgap is defined as an energy difference between top of the valence band and the bottom of conduction band in a semiconductor material

Additional details of the above-described method, as well as tandem solar cells using perovskite materials are provided below.

### BRIEF DESCRIPTION OF THE DRAWINGS

FIG. 1 is a partial cross-sectional view of an exemplary silicon (Si) solar cell (prior art).

FIG. 2 is a partial cross-sectional view of an exemplary CIGS solar cell (prior art).

FIGS. 3A and 3B are schematic partial cross-sectional views of conventional perovskite solar cells (prior art).

FIG. 4 is a partial cross-sectional view of a tandem solar cell using a perovskite material with an adjustable bandgap.

FIG. 5 is a partial cross-sectional view depicting a variation of the bottom subcell of FIG. 4.

FIG. 6 is a partial cross-sectional view of a variation of the tandem solar cell using a perovskite material with an adjustable bandgap.

FIGS. 7A through 7C are partial cross-sectional views depicting variations of bottom subcell for use with the tandem solar cell of FIG. 6.

FIGS. 8A through 8E are an x-ray diffraction (XRD) pattern of the ethylammonium iodide perovskite (FIG. 8A from literature data—prior art), x-ray diffraction analysis of the films prepared using different compositions (FIGS. 8B and 8C), and the absorbance spectra of the samples obtained using different compositions (FIGS. 8D and 8E).

FIGS. 9A and 9B are graphs respectively depicting external quantum efficiency (EQE) and IV scan in the forward direction.

FIG. 10 is a flowchart illustrating a method for preparing a thin film of perovskite material having an adjustable bandgap.

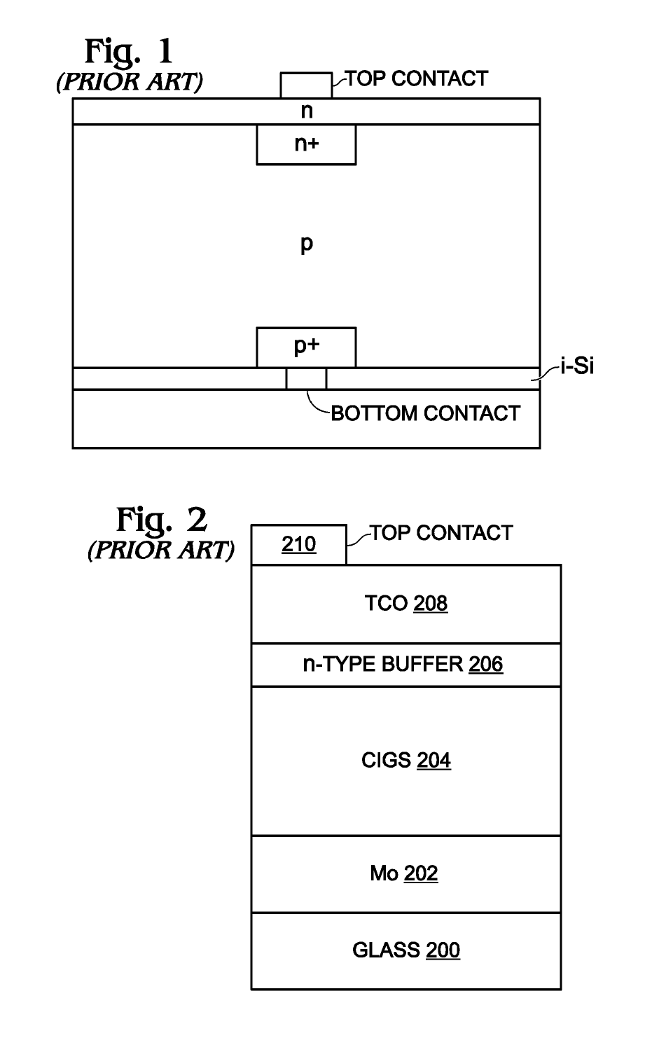

### DETAILED DESCRIPTION

As used herein, perovskite is a material with the same structure as calcium titanate (CaTiO₃), or ABX₃. The B cation is in 6-fold coordination forming an octahedron, while A cations occupy interstitial spaces and exhibit 12-fold coordination.

A semiconductor is a material whose conductivity, due to charges of both signs, is normally in the range between that of metals and insulators and in which the electric charge carrier density can be changed by external means.

N-type semiconductors have a larger electron concentration than hole concentration. The phrase ‘n-type’ comes from the negative charge of the electron. In n-type semiconductors, electrons are the majority carriers and holes are the minority carriers. N-type semiconductors are created by doping an intrinsic semiconductor with donor impurities. In an n-type semiconductor, the Fermi level is greater than that of the intrinsic semiconductor and lies closer to the conduction band than the valence band.

As opposed to n-type semiconductors, p-type semiconductors have a larger hole concentration than electron concentration. The phrase ‘p-type’ refers to the positive charge of the hole. In p-type semiconductors, holes are the majority carriers and electrons are the minority carriers. P-type semiconductors are created by doping an intrinsic semiconductor with acceptor impurities (or doping an n-type semiconductor). For p-type semiconductors the Fermi level is below the intrinsic Fermi level and lies closer to the valence band than the conduction band.

A contact/semiconductor refers to p- or n-type semiconductor which is in contact with absorber material and performs the function of selective carrier extraction.

A tunneling or recombination layer provides a low resistance connection between the bottom and top subcells, without optical interference.

Ammonium cations are defined herein as positively charged ions with the chemical formula of NH₄⁺, where all or some of the hydrogen atoms can be substituted with the alkyl or other alternative organic moiety groups.

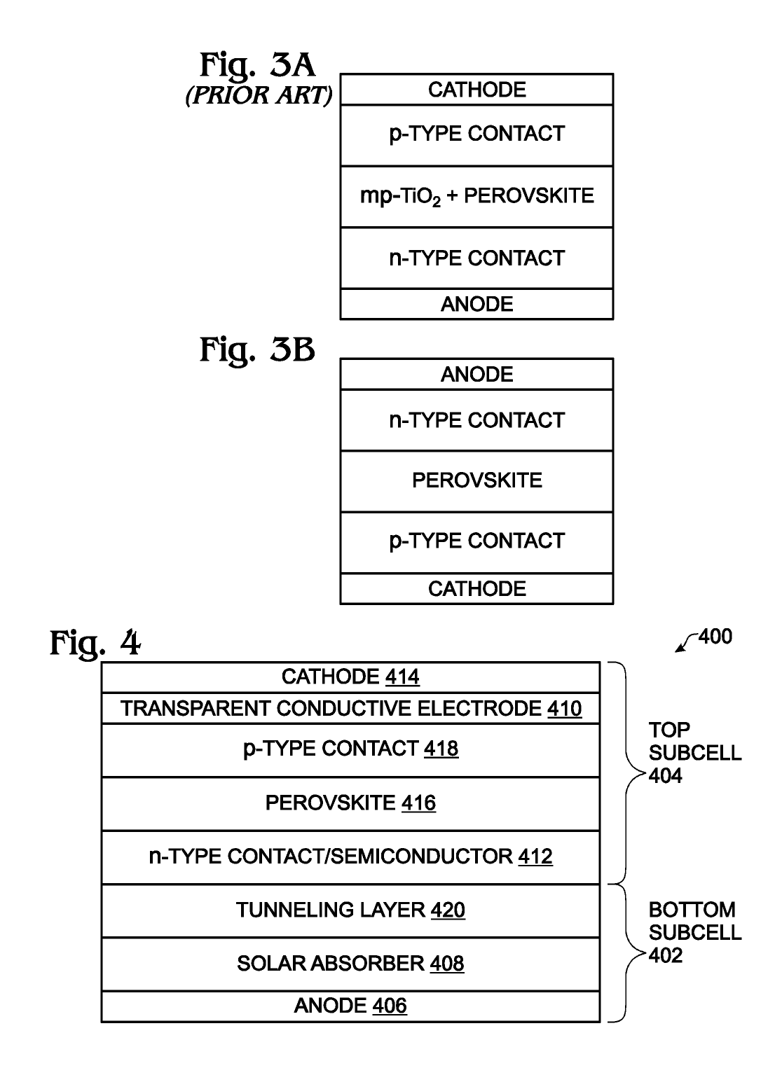

FIG. 4 is a partial cross-sectional view of a tandem solar cell using a perovskite material with an adjustable bandgap. The tandem solar cell 400 comprises a bottom subcell 402 and a top subcell 404. The bottom subcell 402 has an anode 406, a solar absorber material 408, and optionally as shown, a tunneling layer 420 overlying the solar absorber 408. The top subcell 404 comprises a cathode 414, a perovskite layer 416 overlying an n-type contact/semiconductor 412, a p-type contact 418 overlying the perovskite layer, a transparent conductive electrode 410 overlying the p-type contact 418, and the cathode. In one aspect, the n-type contact/semiconductor may be considered as part of the bottom subcell, in which case the tunneling layer can be eliminated.

The perovskite material has the formula A¹_{1-Y}A²_{y}BX₃;
where anionic part X is a halide;
where cation B is lead (Pb), tin (Sn), or germanium (Ge);
where cation A¹ is formamidinium; and,
where cation A² is an organic cation having a larger size than a methylammonium cation.

The A² cation may be an ammonium cation such as ethylammonium, guanidinium, dimethylammonium, acetamidinum, or substituted derivatives of the above-mentioned ammonium cations. In one aspect, the perovskite has the formula FA_{1-y}EtA_{Y}PbI₃, where FA is formamidinium, I is iodide, and Et is ethylammonium.

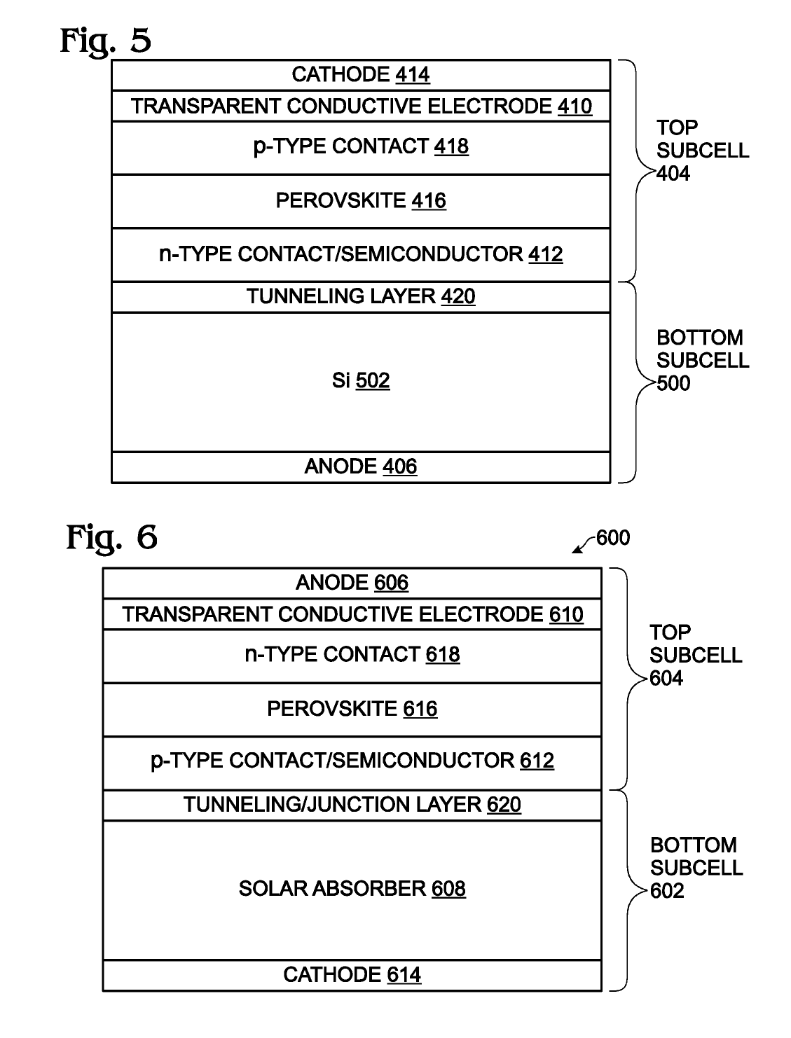

FIG. 5 is a partial cross-sectional view depicting a variation of the bottom subcell of FIG. 4. The bottom cell 500 is a silicon cell with a silicon layer 502. The silicon subcell has a bandgap in the range of 1.6 to 1.7 electron volts (eV). Optionally, a tunneling layer 420 is used. The tunneling layer 420 allows charges from the top subcell to recombine with opposite charges from the bottom subcell.

FIG. 6 is a partial cross-sectional view of a variation of the tandem solar cell using a perovskite material with an adjustable bandgap. This tandem solar cell 600 comprises a bottom subcell 602 and a top subcell 604. The bottom subcell 602 has a cathode 614, a solar absorber material 608, and a tunneling/junction layer 620. The top subcell 604 is connected to the bottom subcell tunneling/junction layer 620. The top subcell 604 has an anode 606, a p-type contact/semiconductor 612 overlying the tunneling/junction layer 620, a perovskite layer 616 overlying a p-type contact/semiconductor 612, and an n-type contact 618 interposed between the perovskite layer and a transparent conductive electrode 610.

The perovskite material has the formula A¹_{1-Y}A²_{y}BX₃;
where anionic part X is a halide;
where cation B is Pb, Sn, or Ge;
where cation A¹ is formamidinium; and,
where cation A² is an organic cation having a larger size than a methylammonium cation.

The A² cation may be an ammonium cation such as ethylammonium, guanidinium, dimethylammonium, acetamidinum, or substituted derivatives of the above-mentioned ammonium cations. In one aspect, the perovskite has the formula FA_{1-y}EtA_{Y}PbI₃, where FA is formamidinium, I is iodide, and Et is ethylammonium.

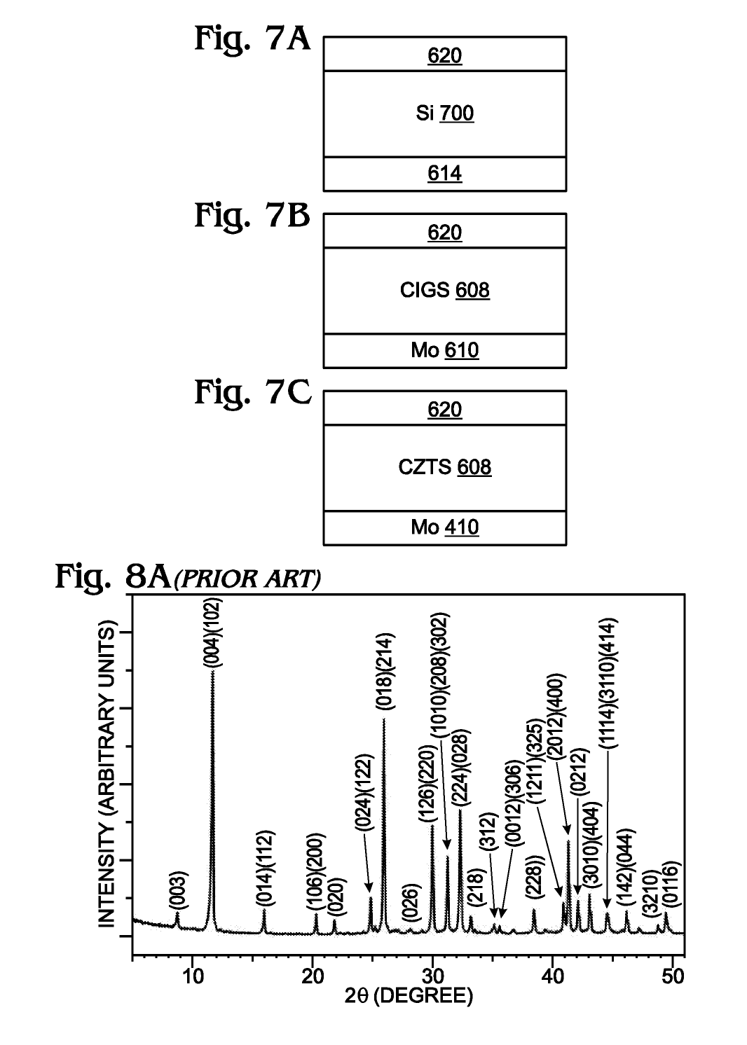

FIGS. 7A through 7C are partial cross-sectional views depicting variations of the bottom subcell for use with the tandem solar cell of FIG. 6. In FIG. 7A the bottom cell 622 is a silicon cell with a silicon layer 700 overlying the anode 614. Tunneling layer 620 overlies the silicon layer 700. The silicon cell has a bandgap in the range of 1.6 to 1.7 electron volts (eV). In FIG. 7B the bottom subcell 602 is a CIGS solar cell where the solar absorber 608 is a CIGS absorber layer, with the tunneling/junction layer 620 acting as an n-type buffer layer. The CIGS bottom subcell has a bandgap in the range of 1.0 to 1.7 eV. Alternatively, in a variation of CIGS (not shown), the bottom subcell may be a copper indium sulfide/selenide (CIS) solar cell with a CIS absorber layer.

In FIG. 7C the bottom subcell 602 is a CZTS solar cell where the solar absorber is a CZTS absorber layer 608, with tunneling/junction layer 620 acting as an n-type buffer layer. The CZTS bottom subcell 602 has a bandgap in the range 1.0 to 1.6 eV.

In one aspect, a perovskite thin film is fabricated as follows:

1. Use evaporation to deposit a thin (about 100 nm) lead iodide film under vacuum.

2. Expose the thin film sample through dropping an organic precursor solution that contains formamidinium iodide and ethylammonium iodide. Wait for about 5 seconds of perovskite conversion time and then spin-off the excess solution.

3. Repeat the procedure about 3 times to achieve a full conversion.

The color of the sample, and the bandgap tuning, changes with the degree of conversion. With respect to morphology, it is well-known that perovskite having different cations may crystallize in different ways (i.e. crystal shapes). For example, methylammonium perovskites tend to form cuboids several hundred nanometers in size, whereas formamidinium perovskite tends to form nanowires. Therefore, the evaluation of the method should be done from the prospective of the film morphology. This is of particular importance to verify the methods' applicability to the preparation of the films suitable for further fabrication of the tandem structures.

Perovskite morphology depends on the material composition. Sample #1 was prepared using ethylammonium iodide (EtAI) only (10 mg/mL). Sample #2 was a mixed composition (7.5 mg/mL of EtAI and 2.5 mg/mL of FAI). Sample #3 was a mixed composition (5 mg/mL of EtAI and 5 mg/mL of FAI). Sample #4 was pure formamidinium iodide. A scanning electron microscope (SEM) revealed that pure EtAI perovskite crystallizes in a manner conducive to thin film fabrication. However, the mixed compositions are more promising for adopting a planar top surface morphology and the thin films are suitable for further processing into a tandem solar cell structure. In principle, the method can also be applied to other perovskite compositions, based not only on lead, but also on tin or germanium perovskites. Moreover, the composition of the cation mix is not limited to formamidinium, ethylammonium mixture.

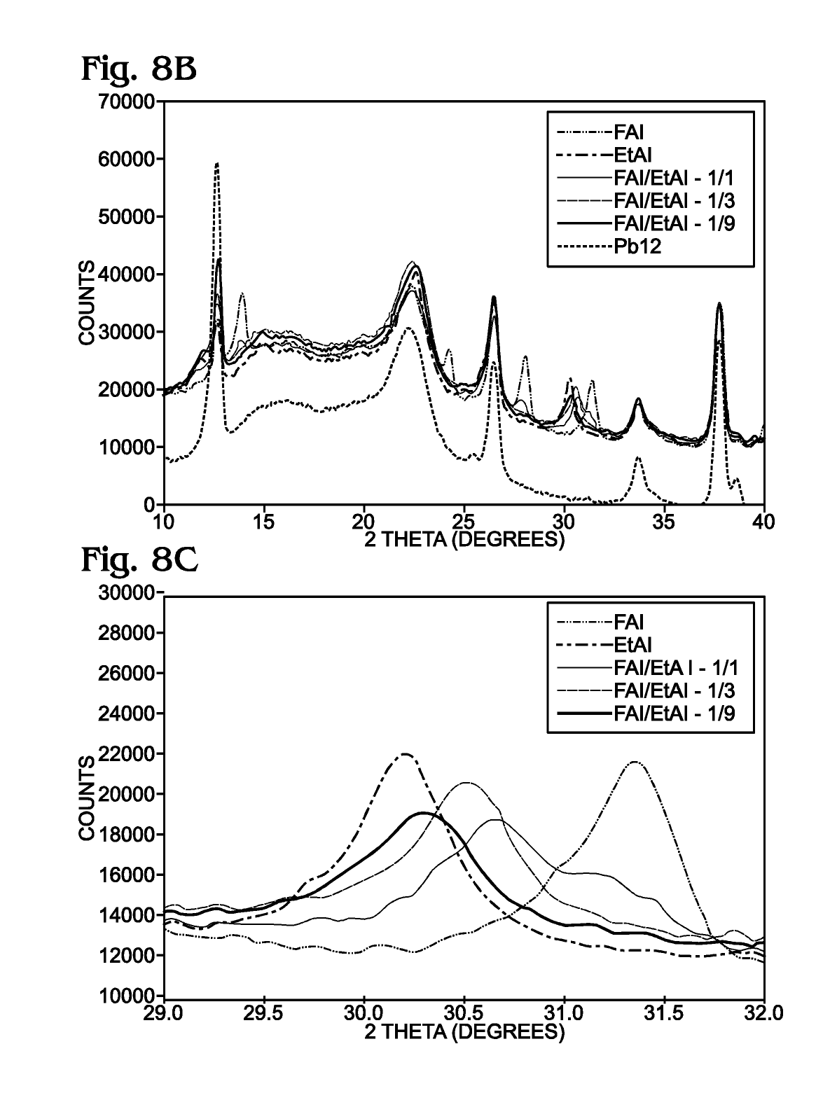

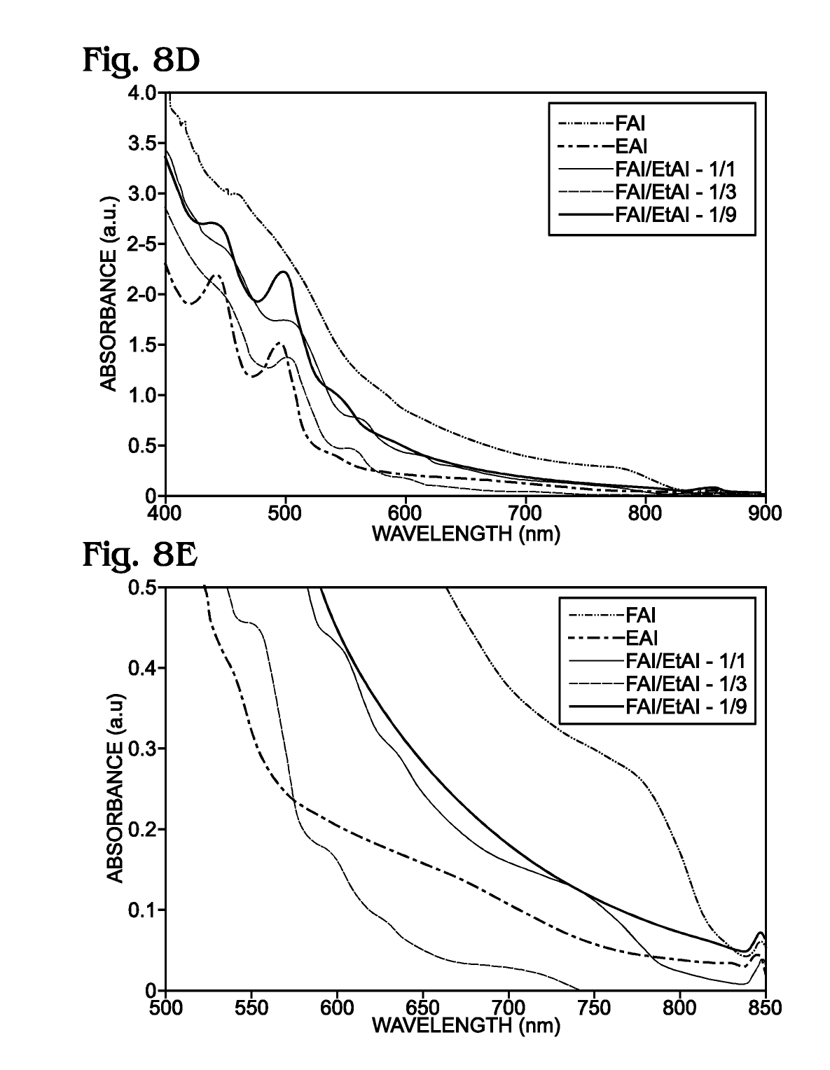

FIGS. 8A through 8E are an x-ray diffraction (XRD) pattern of the ethylammonium iodide perovskite (FIG. 8A from literature data—prior art), x-ray diffraction analysis of the films prepared using different compositions (FIGS. 8B and 8C), and the absorbance spectra of the samples obtained using different compositions (FIGS. 8D and 8E). Another approach for the characterization of the material with the mixed composition was carried out using optical spectroscopy and XRD. For this study, in addition to the pure formamidinium (FAI) and ethylammonium (EtAI) iodides solutions (10 mg/mL in isopropanol), also prepared were solutions with the mixed compositions FAI:EtAI—1:1, 1:3, 1:9 (by weight).

The films prepared using a combination of the FAI and EtAI demonstrated a transition between two phases, and are proof of concept for the tunability of the bandgap of the perovskite material. Interestingly, for the samples of the mixed composition, a clear transition of the perovskite diffraction peak is observed (at around 30 two theta). This observation supports the hypothesis that a true alloy is formed rather than two separate phases.

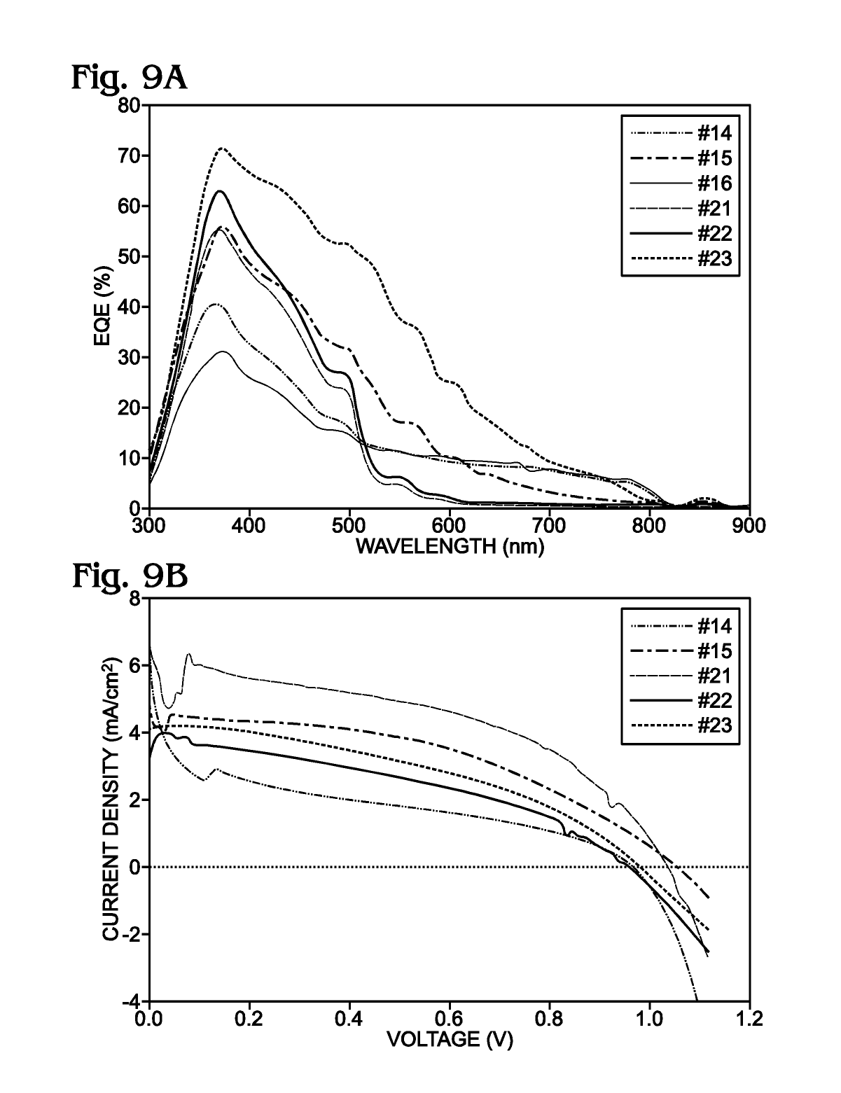

FIGS. 9A and 9B are graphs respectively depicting external quantum efficiency (EQE) and IV scan in the forward direction. To provide an additional proof of the adjustment characteristics of the band structure of the material, several perovskite-based devices with planar architecture were fabricated using the conditions provided in Table 1. The devices were based on spray-pyrolysis of compact titanium dioxide layer on FTO glass, followed by the deposition of the perovskite material described above and finalized using conventional doped SPIRO-OMeTAD as the hole transporting layer, and gold as counter electrode.

TABLE 1
Condition of the perovskite conversion.

| Sample ID | Conversion solution composition |
|---|---|
| 14, 16 | FAI pure |
| 15, 23 | 50% FAI:50% EtAI |
| 22, 21 | 25% FAI:75% EtAI |

The devices fabricated with the mixed composition of organic cations demonstrated that there is an optimal composition range where bandgap adjustment can be made (at relatively low amounts of EtAI). In such a case, as represented by the devices #15 and 23, even the cell voltage could be increased due the change of the band structure of the absorber material.

Thus, a new pathway is provided for the adjustment of the bandgap of the formamidinium lead perovskite material through the fine adjustment of the organic cation composition. In principle, this procedure can be applied to the other hybrid perovskite materials, such as methylamonium or cesium based iodoplumbates. The addition of the second organic cation, larger than the original allows the band structure to be tuned. This process can possibly be performed not only with ethylammonium iodide, but also with other examples of substituted amines, which would cause a major structural change.

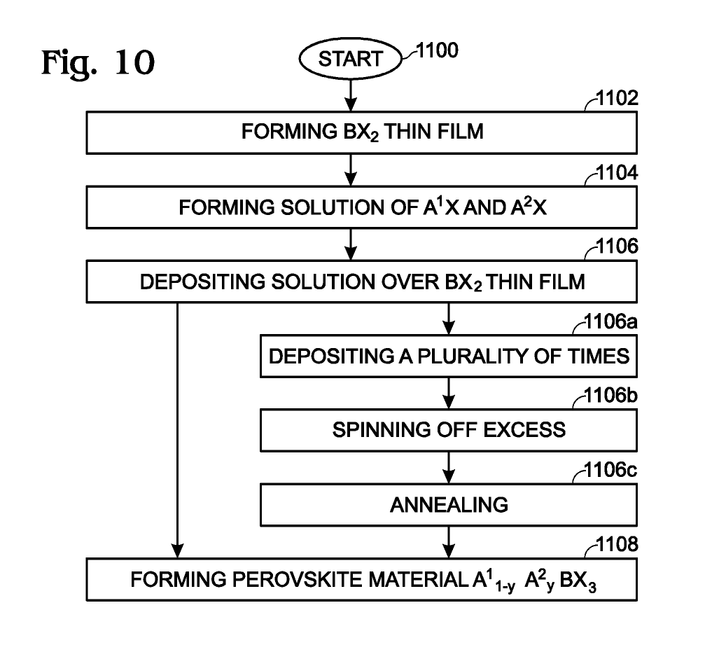

FIG. 10 is a flowchart illustrating a method for preparing a thin film of perovskite material having an adjustable bandgap. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. Generally however, the method follows the numeric order of the depicted steps. The method starts at Step 1100.

Step 1102 forms a thin film of material having the formula BX₂,
where anionic part X is a halide; and.
where cation B is Pb, Sn, or Ge.

Step 1104 forms a solution of materials comprising the formulas A¹X and A²X,
where cation A1 is formamidinium; and,
where cation A2 is an organic cation having a larger size larger than a methylammonium cation.

Step 1106 deposits the solution over the BX₂ thin film. Step 1108 forms a perovskite material having the formula A¹_{1-Y}A²_{y}BX₃.

In one aspect, depositing the solution over the BX₂ thin film in Step 1106 includes substeps. Step 1106a deposits the solution a plurality of times. Step 1106b spins off excess solution after each deposition. Step 1106c anneals. The annealing may be performed after every deposition steps or just once, after the final deposition step. In another aspect, forming the solution in Step 1104 includes the A² cation being ammonium cations, such as ethylammonium, guanidinium, dimethylammonium, acetamidinium, or substituted derivatives of the above-mentioned ammonium cations.

In one aspect, forming the perovskite material in Step 1108 includes A¹BX₃ being formamidinium iodide (FAI) and A²BX₃ being ethylammonium iodide (EtAI). The FAI and EtAI may form a material with the formula FA_{1-y}EtA_{Y}PbI₃. Further, the bandgap of the perovskite material formed in Step 1108 is responsive to the proportion of EtAI to FAI, where a bandgap is defined as an energy difference between top of the valence band and the bottom of conduction band in a semiconductor material.

While the use of evaporation has been described above in the deposition of lead iodide films, other methodologies for the film deposition may be utilized as well. Likewise, the organic materials can be deposited not only through spin-coating, but through other solution-based deposition methodologies, such as printing for instance.

A method for preparing a thin film of perovskite material having an adjustable bandgap has been provided, along with tandem solar cells made with such a perovskite material. Examples of particular chemical compositions and process steps have been presented to illustrate the invention. However, the invention is not limited to merely these examples. Other variations and embodiments of the invention will occur to those skilled in the art.

We claim:

1. A method for preparing a thin film of perovskite material having an adjustable bandgap, the method comprising:
forming a thin film of material having the formula BX₂,
where anionic part X is a halide;
where cation B is selected from the group consisting of lead (Pb), tin (Sn), and germanium (Ge);
forming a solution of materials comprising the formulas A¹X and A²X,
where cation A¹ is formamidinium;
where cation A² is an organic cation having a larger size larger than a methylammonium cation;
depositing the solution over the BX₂ thin film; and,
forming a perovskite material having the formula A¹_{1-Y}A²_{y}BX₃.

2. The method of claim 1 wherein depositing the solution over the BX₂ thin film includes:
depositing the solution a plurality of times:
spinning off excess solution after each deposition; and,
annealing.

3. The method of claim 1 wherein forming the solution includes the A² cation being selected from the group of ammonium cations consisting of ethylammonium, guanidinium, dimethylammonium, acetamidinium, and substituted derivatives of the above-mentioned ammonium cations.

4. The method of claim 3 wherein forming the perovskite material includes A¹BX₃ being formamidinium iodide (FAI) and A²BX₃ being ethylammonium iodide (EtAI).

5. The method of claim 4 wherein forming the perovskite materials includes the FAI and EtAI forming a material with the formula FA_{1-y}EtA_{Y}PbI₃

6. The method of claim 4 wherein forming the perovskite material includes the bandgap of the perovskite material being responsive to the proportion of EtAI to FAI, where a bandgap is defined as an energy difference between top of the valence band and the bottom of conduction band in a semiconductor material.

7. A tandem solar cell using a perovskite material with an adjustable bandgap, the tandem solar cell comprising:
a bottom subcell having an anode and a solar absorber material; and,
a top subcell comprising:
an n-type contact/semiconductor overlying the solar absorber;
a perovskite layer overlying the n-type contact/semiconductor;
a p-type contact overlying the perovskite layer;
a transparent conductive electrode overlying the p-type contact;
a cathode overlying the transparent conductive electrode;
wherein the perovskite material has the formula A¹_{1-Y}A²_{y}BX₃;
where anionic part X is a halide;
where cation B is selected from the group consisting of lead (Pb), tin (Sn), and germanium (Ge);
where cation A¹ is formamidinium; and,
where cation A² is an organic cation having a larger size than a methylammonium cation.

8. The tandem solar cell of claim 7 wherein the bottom subcell further comprises a tunneling layer interposed between the solar absorber and n-type contact/semiconductor.

9. The tandem solar cell of claim 7 wherein the A² cation is selected from the group of ammonium cations consisting of ethylammonium, guanidinium, dimethylammonium, acetamidinum, and substituted derivatives of the above-mentioned ammonium cations.

10. The tandem solar cell of claim 7 wherein the perovskite has the formula FA_{1-y}EtA_{Y}PbI₃, where FA is formamidinium, I is iodide, and Et is ethylammonium.

11. A tandem solar cell using a perovskite material with an adjustable bandgap, the tandem solar cell comprising:
a bottom subcell having an anode and silicon; and,
a top subcell comprising:
an n-type contact/semiconductor overlying the p-doped silicon;
a perovskite layer overlying the n-type contact/semiconductor;
a p-type contact overlying the perovskite layer;
a transparent conductive electrode overlying the p-type contact;
a cathode overlying the transparent conductive electrode;
wherein the perovskite material has the formula A¹_{1-Y}A²_{y}BX₃;
where anionic part X is a halide;
where cation B is selected from the group consisting of lead (Pb), tin (Sn), and germanium (Ge);
where cation A¹ is formamidinium; and,
where cation A² is an organic cation having a larger size than a methylammonium cation.

12. The tandem solar cell of claim 11 wherein the bottom subcell further comprises a tunneling layer interposed between the silicon and the n-type contact/semiconductor.

13. The tandem cell of claim 11 where the bottom subcell has a bandgap in a range of 1.6 to 1.7 electron volts (eV).

14. A tandem solar cell using a perovskite material with an adjustable bandgap, the tandem solar cell comprising:
a bottom subcell comprising a cathode, solar absorber material, and a tunneling/junction layer; and,
a top subcell comprising:
a p-type contact/semiconductor overlying the tunneling/junction layer;
a perovskite layer overlying the p-type contact/semiconductor;
an n-type contact overlying the perovskite layer;
a transparent conductive electrode overlying the n-type contact,
an anode overlying the transparent conductive electrode;
wherein the perovskite material has the formula A¹_{1-Y}A²_{y}BX₃;
where anionic part X is a halide;
where cation B is selected from the group consisting of lead (Pb), tin (Sn), and germanium (Ge);
where cation A¹ is formamidinium; and,
where cation A² is an organic cation having a larger size than a methylammonium cation.

15. The tandem solar cell of claim 14 wherein the bottom subcell is a copper indium gallium selenide (CIGS) solar cell comprising a CIGS absorber layer, or a copper indium sulfide/selenide (CIS) solar cell with a CIS absorber layer, with the tunneling/junction layer acting as an n-type buffer layer, and having a bandgap in a range of 1.0 to 1.7 eV.

16. The tandem solar cell of claim 14 wherein the A² cation is selected from the group of ammonium cations consisting of ethylammonium, guanidnium, dimethylammonium, acetamidinum, and substituted derivatives of the above-mentioned ammonium cations.

17. The tandem solar cell of claim 14 wherein the perovskite has the formula FA_{1-y}EtA_{Y}PbI₃, where FA is formamidinium, I is iodide, and Et is ethylammonium.

18. The tandem solar cell of claim 14 wherein the bottom subcell is a copper zinc tin selenide/sulfide (CZTS) solar cell comprising a CZTS absorber layer, with the tunneling/junction layer acting as an n-type buffer layer, and having a bandgap in a range 1.0 to 1.6 eV.

19. A tandem solar cell using a perovskite material with an adjustable bandgap, the tandem solar cell comprising:
a bottom subcell comprising an anode, a silicon layer, and a tunneling/junction layer; and,
a top subcell comprising:
a p-type contact/semiconductor overlying the tunneling/junction layer;
a perovskite layer overlying the p-type contact/semiconductor;
an n-type contact overlying the perovskite layer;
a transparent conductive electrode overlying the n-type contact,
a cathode overlying the transparent conductive electrode;
wherein the perovskite material has the formula A¹_{1-Y}A²_{y}BX₃;
where anionic part X is a halide;
where cation B is selected from the group consisting of lead (Pb), tin (Sn), and germanium (Ge);
where cation A¹ is formamidinium; and,
where cation A² is an organic cation having a larger size than a methylammonium cation.

20. The tandem solar cell of claim 19 wherein the bottom subcell has a bandgap in a range of 1.6 to 1.7 electron volts (eV).
